(19) United States
(12) Patent Application Publication
(10) Pub. No.: US 2025/0149973 A1
(43) Pub. Date: May 8, 2025

(54) POWER SUPPLY SYSTEM AND VOLTAGE DETECTION METHOD

(71) Applicant: DELTA ELECTRONICS, INC., Taoyuan City (TW)

(72) Inventors: Li-Ching YANG, Taoyuan City (TW); Wen-Lung HUANG, Taoyuan City (TW); Sheng-Hua LI, Taoyuan City (TW)

(21) Appl. No.: 18/648,353

(22) Filed: Apr. 27, 2024

(30) Foreign Application Priority Data
Nov. 7, 2023 (CN) 202311476215.6

(51) Int. Cl. H02M 1/088; H02M 1/00; H02M 1/32

(52) U.S. Cl. CPC H02M 1/088; H02M 1/0022; H02M 1/32

(57) ABSTRACT

A power supply system includes a voltage conversion circuit and at least one voltage detector. The voltage conversion circuit converts AC voltage into DC voltage. The voltage detector includes a voltage dividing circuit, a phase voltage detection circuit, and a line voltage detection circuit. The voltage dividing circuit is coupled to the voltage conversion circuit to receive AC voltage. The voltage dividing circuit includes multiple impedance elements and multiple voltage dividing nodes to output multiple divided voltages. The phase voltage detection circuit is coupled to one of the voltage dividing nodes of voltage dividing circuit to generate a phase voltage detection signal based on one of the divided voltages. The line voltage detection circuit is coupled to a part of the voltage dividing nodes of voltage dividing circuit to generate a line voltage detection signal based on a part of the divided voltages.

### RELATED APPLICATIONS

This application claims priority to China Application Serial Number 202311476215.6, filed Nov. 7, 2023, which is herein incorporated by reference.

### BACKGROUND

### Field of Invention

The present disclosure relates to a power supply system. More particularly, the present disclosure relates to a power supply system and a voltage detection method.

### Description of Related Art

With the rapid development of economy and industry, the importance of power systems is increasing day by day. Generally speaking, most of the industrial equipment is driven by direct current (DC) power. Therefore, a conversion device is necessary between the power distribution system and the equipment to convert the alternating current (AC) power provided by the power grid into DC power. The stability of the electric power during the transmission and conversion processes is one of the important performance indicators of the power system.

For the foregoing reason, there is a need to solve the above-mentioned problem by providing a power supply system and a voltage detection method.

### SUMMARY

A power supply system is provided. The power supply system includes a voltage conversion circuit and at least one voltage detector. The voltage conversion circuit is configured to convert an AC (alternating current) voltage into a DC voltage. The voltage detector includes a voltage dividing circuit, a phase voltage detection circuit, and a line voltage detection circuit. The voltage dividing circuit is coupled to the voltage conversion circuit to receive the AC voltage. The voltage dividing circuit includes a plurality of impedance elements and a plurality of voltage dividing nodes to output a plurality of divided voltages. The phase voltage detection circuit is coupled to one of the voltage dividing nodes of the voltage dividing circuit to generate a phase voltage detection signal based on one of the divided voltages. The line voltage detection circuit is coupled to a part of the voltage dividing nodes of the voltage dividing circuit to generate a line voltage detection signal based on a part of the divided voltages.

The present disclosure provides a voltage detection method. The voltage detection method includes: coupling a first voltage detector to a plurality of first detection nodes of a medium voltage system cabinet, and coupling a second voltage detector to a plurality of second detection nodes of the medium voltage system cabinet, in which the first detection nodes are coupled between a plurality of phase voltage input nodes and a plurality of first circuit elements, and the second detection nodes are coupled between the first circuit elements and a plurality of second circuit elements; obtaining a plurality of first phase voltage detection signals of the first detection nodes through the first voltage detector, and obtaining a plurality of second phase voltage detection signals of the second detection nodes through the second voltage detector; determining whether the first phase voltage detection signals and the second phase voltage detection signals are normal or not through a controller; and generating an abnormal signal when the first phase voltage detection signals are normal but one of the second phase voltage detection signals is abnormal.

Accordingly, through using the same voltage dividing circuit to provide the divided voltages to the phase voltage detection circuit and the line voltage detection circuit, the structure of the voltage detector can be simplified. In addition, by obtaining the phase voltage detection signals respectively at different detection nodes, the abnormal circuit element in the medium voltage system cabinet can be quickly and accurately confirmed.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 depicts a schematic diagram of a power supply system according to some embodiments of the present disclosure;

FIG. 2 depicts a schematic diagram of a voltage detector and a controller according to some embodiments of the present disclosure;

FIG. 3 depicts a flowchart of a voltage detection method according to some embodiments of the present disclosure;

FIG. 4A depicts a waveform diagram of phase voltages detected by a power supply system according to some embodiments of the present disclosure;

FIG. 4B depicts a waveform diagram of phase voltages detected by a power supply system according to some embodiments of the present disclosure;

FIG. 5 depicts a schematic diagram of a voltage detector according to some embodiments of the present disclosure;

FIG. 6A-FIG. 6C depict schematic diagrams of voltage detectors according to some embodiments of the present disclosure; and

FIG. 7 depicts a flowchart of a voltage detection method according to some embodiments of the present disclosure.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and elements/components are schematically depicted in order to simplify the drawings.

In this document, the term “coupled” may also be termed “electrically coupled,” and the term “connected” may be termed “electrically connected.” “Coupled” and “connected” may also be used to indicate that two or more elements/components cooperate or interact with each other. It will be understood that, although the terms “first,” “second,” etc., may be used herein to describe various elements/components, these elements/components should not be limited by these terms. These terms are used to distinguish one element/component or operation from another. For example, a first element/component could be termed a second element/component, and, similarly, a second element/component could be termed a first element/component, without departing from the scope of the embodiments.

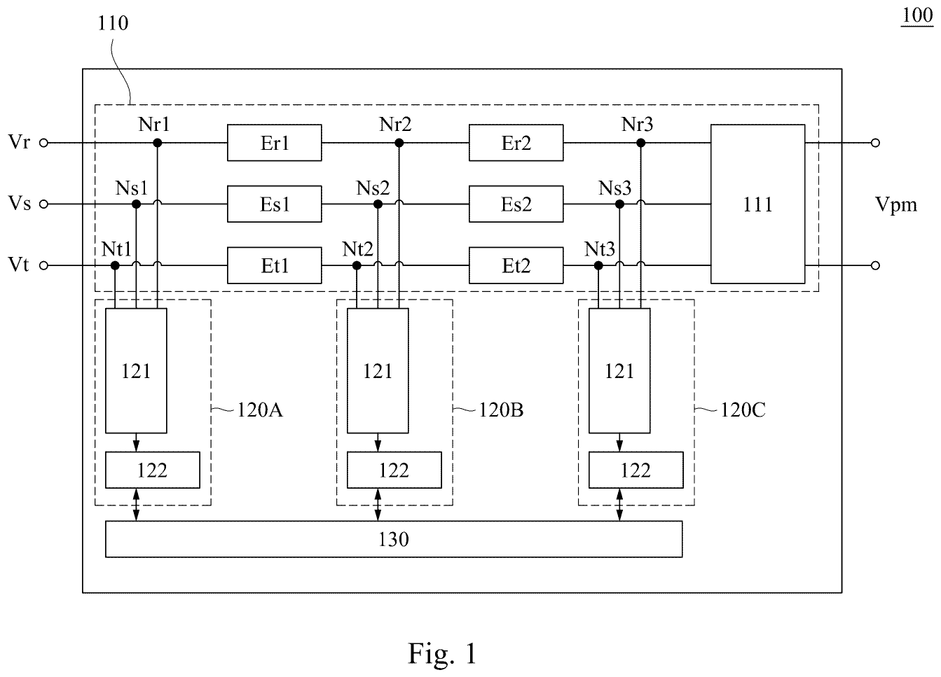

FIG. 1 depicts a schematic diagram of a power supply system 100 according to some embodiments of the present disclosure. In one embodiment, the power supply system 100 may be applied as a medium voltage system cabinet (such as a solid-state transformer, a medium voltage substation, or a medium voltage frequency converter) to convert an AC voltage provided by a power grid into a DC voltage Vpm. Here “medium voltage” refers to the voltage applied to transmitting/converting kilovolts (Kv), for example: 10 kV-35 kV. However, the present disclosure is not limited in this regard.

The power supply system 100 (the medium voltage system cabinet) includes a voltage conversion circuit 110, one or more voltage detector 120A-120C, and a controller 130. The voltage conversion circuit 110 is configured to receive multiple AC voltages through multiple phase voltage input nodes. In one embodiment, the voltage conversion circuit 110 is configured to receive a three-phase voltage of 10 kV to 35 kV, that is, AC voltages Vr/Vs/Vt marked in FIG. 1. A number of the voltage detectors may be arbitrarily adjusted depending on the detection requirements (such as a number of nodes that need to be detected in the power supply system 100).

As shown in FIG. 1, the voltage conversion circuit 110 includes a plurality of circuit elements having different functions and a power control circuit 111, and the power control circuit 111 is coupled to the circuit elements and the controller 130. In one embodiment, the circuit elements can be divided into first circuit elements (such as protection elements Er1, Es1, Et1) and second circuit elements (such as power switching elements Er2, Es2, Et2), and are configured to form a plurality of conversion subcircuits. For example, a first conversion subcircuit includes the protection element Er1 and the power switching element Er2 and is configured to receive an R-phase AC voltage, the second conversion subcircuit includes the protection element Es1 and the power switching element Es2 and is configured to receive an S-phase AC voltage, the third conversion subcircuit includes the protection element Et1 and the power switching element Et2 and is configured to receive a T-phase AC voltage. Phases of the R-phase, S-phase, and T-phase AC voltages are 120 degrees different from one another.

The first circuit elements, that is, the protection elements Er1/Es1/Et1 are configured to disconnect the power control circuit 111 from the AC voltages Vr/Vs/Vt when an overcurrent occurs on the conversion subcircuits (such as an inrush current). In other words, when currents flowing through the protection elements Er1/Es1/Et1 exceed a set threshold value, the corresponding protection elements will turn off by themselves (that is, they will turn off according to their element characteristics to form open circuits). The protection elements Er1/Es1/Et1 may be implemented by fuses or overcurrent protection elements. The second circuit elements, that is, the power switching elements Er2, Es2, Et2, are configured to be selectively turned on or off so as to control inputs of the AC voltages Vr/Vs/Vt. For example, when the R-phase AC voltage Vr is excessively high, the power switching element Er2 will be controlled to be turned off by the controller 130 to prevent the excessive voltage from damaging the power supply system 100 (the medium voltage system cabinet). The power switching elements Er2, Es2, and Et2 may be implemented by relays or contactors.

For the convenience of subsequent explanation, here “the nodes between the phase voltage input nodes and the first circuit elements (for example: the protection elements Er1/Es1/Et1)” are called first detection nodes Nr1/Ns1/Nt1; “the nodes between the first circuit elements (for example, the protection elements Er1/Es1/Et1) and the second circuit elements (for example, the power switching element Er2/Es2/Et2)” are called second detection node Nr2/Ns2/Nt2; “the nodes between the second circuit elements (for example, the power switching element Er2/Es2/Et2) and the power control circuit 111” are called third detection nodes Nr3/Ns3/Nt3.

The voltage detectors 120A-120C are respectively connected to the first detection nodes Nr1/Ns1/Nt1, the second detection nodes Nr2/Ns2/Nt2, and the third detection nodes Nr3/Ns3/Nt3, and are configured to detect phase voltages and line voltages. The line voltage (line to line voltage) refers to a voltage between phase voltages of different phases, and is also called phase-to-phase voltage.

The controller 130 is coupled to the voltage detectors 120A-120C, and is configured to receive the phase voltages and line voltages detected by the voltage detectors 120A-120C, and determine whether internal circuit elements are abnormal or not based on the detected phase voltages. The controller 130 can further transmit the detected line voltages to the power control circuit 111 so as to perform a phase lock control (such as generating clock signals for controlling various circuit elements in the power supply system 100) or adjust a power factor (such as adjusting the switching frequencies of the various circuit elements in the power supply system 100).

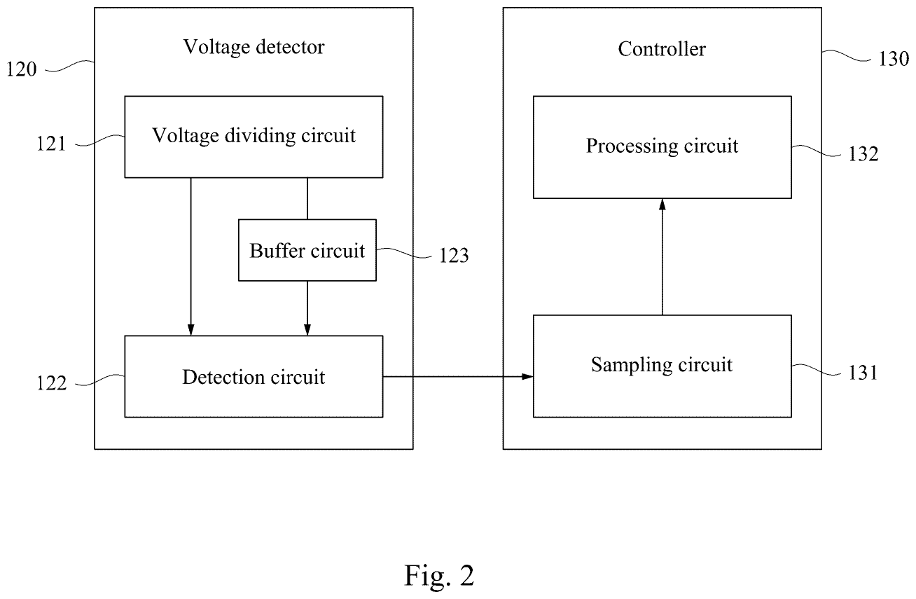

FIG. 2 depicts a schematic diagram of the voltage detector 120 and the controller 130. The voltage detector 120 shown in FIG. 2 can be applied to any of the voltage detectors 120A-120C in FIG. 1. The voltage detector 120 includes a voltage dividing circuit 121 and a detection circuit 122. The voltage dividing circuit 121 is coupled to the detection nodes to receive the AC voltages, and generates divided voltages having a lower voltage value based on the AC voltages. The detection circuit 122 is coupled to the voltage dividing circuit 121 and is configured to generate phase voltage detection signals and line voltage detection signals based on the divided voltages.

In some embodiments, a buffer circuit 123 may be disposed between the voltage dividing circuit 121 and the detection circuit 122. The buffer circuit 123 is configured to be decoupled with an adjacent circuit when there is local damage in the detection circuit 122, so that the damaged circuit does not affect or damage the work behaviors of the other voltage dividing circuits 121 or detection circuits 122. The detailed circuit is illustrated in the following paragraphs and drawings.

In one embodiment, the voltage detector 120 integrates a phase voltage detection circuit and a line voltage detection circuit into a same device at the same time to simplify the circuit structure and improve the cost and volume of the circuit. The detailed circuit is illustrated in the following paragraphs and drawings.

The controller 130 includes a sampling circuit 131 and a processing circuit 132. The sampling circuit 131 is coupled to the detection circuit 122, and is configured to receive the phase voltage detection signals and the line voltage detection signals and convert the signals from an analog format to a digital format. The processing circuit 132 is coupled to the sampling circuit 131 and is configured to analyze the phase voltage detection signals and the line voltage detection signals. The processing circuit 132 is configured to determine whether voltages of the voltage detector 120 and the detection nodes are abnormal or not based on the phase voltage detection signals and the line voltage detection signals, and further control the operations of the conversion subcircuits and the power control circuit 111. In greater detail, the processing circuit 132 compares the plurality of phase voltage detection signals (or the plurality of line voltage detection signals) to determine whether there is an abnormality in the plurality of phase voltage detection signals or not.

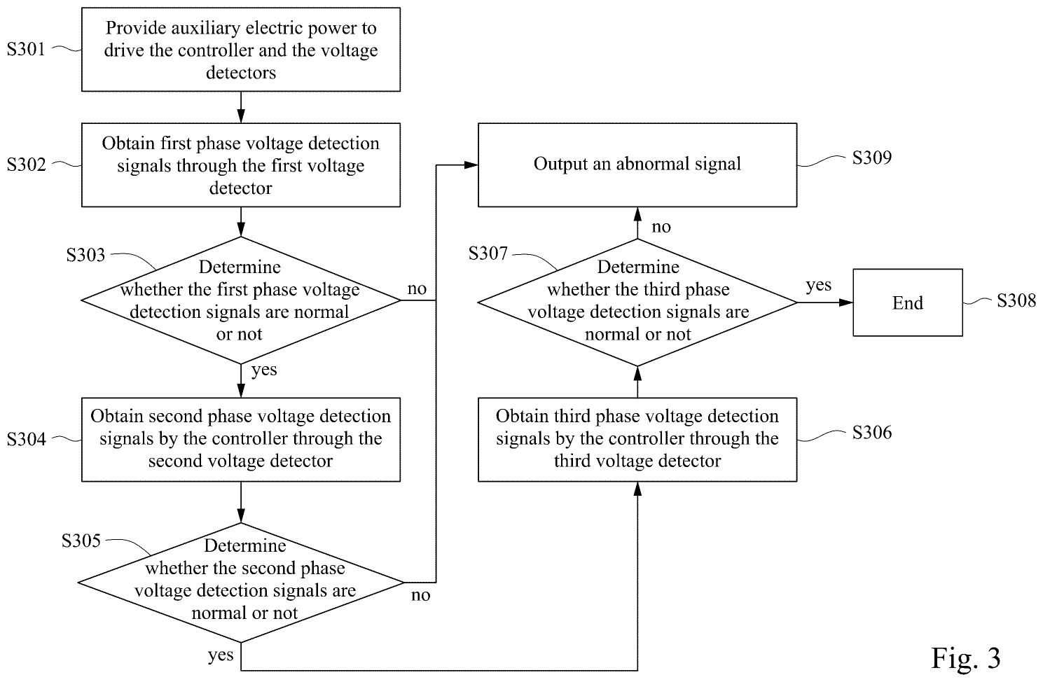

FIG. 3 depicts a flowchart of a voltage detection method according to some embodiments of the present disclosure. In the present embodiment, the power supply system 100 (the medium voltage system cabinet) performs a detection on the voltage conversion circuit 110 through steps S301-S309.

In step S301, when the power supply system 100 receives the AC voltages Vr/Vs/Vt through the phase voltage input nodes, the power supply system 100 will also obtain auxiliary electric power from an auxiliary power supply to drive the controller 130 and the voltage detectors 120A-120C. In one embodiment, the power supply system 100 receives the AC voltages Vr/Vs/Vt through the power grid, and the auxiliary power supply is a power supply device different from the power grid, for example, it is provided by an energy storage device, an uninterruptible power supply, or other low-voltage AC utility power.

In step S302, the first voltage detector 120A obtains a plurality of first phase voltage detection signals corresponding to the first detection nodes Nr1/Ns1/Nt1. In some embodiments, since at this time the first detection nodes Nr1/Ns1/Nt1 are detected, the controller 130 can first turn off the power switching elements Er2/Es2/Et2.

In step S303, the controller 130 determines whether all the first phase voltage detection signals are normal or not. If yes, step S304 is performed. If there is any one in the first phase voltage detection signals to be abnormal (for example: exceed an expected voltage range), step S309 is performed. For example, the controller 130 compares the first phase voltage detection signals. If among the three first phase voltage detection signals, a difference between one another exceeds a preset range (for example: the voltages are respectively 10 kV, 10 kV, 0 kV, and differences are 10 kV), it means that there is an abnormality in the first phase voltage detection signals.

If there is any one in the first phase voltage detection signals to be abnormal, the controller 130 will generate an abnormal signal corresponding to the abnormal first detection node. For example, if the first phase voltage detection signals corresponding to the first detection nodes Nr1/Ns1 are normal but the first phase voltage detection signal corresponding to the first detection node Nt1 is abnormal, it means that a circuit element adjacent to the first detection node Nt1 is probably abnormal (for example, the phase voltage input node receiving the T-phase AC voltage is probably damaged).

In step S304, when the controller 130 receives the first phase voltage detection signals or when the controller 130 determines that all the first phase voltage detection signals are normal, the controller 130 obtains a plurality of second phase voltage detection signals corresponding to the second detection nodes Nr2/Ns2/Nt2 through the second voltage detector 120B.

In step S305, the controller 130 determines whether all the second phase voltage detection signals are normal or not. For example, the controller 130 compares the second phase voltage detection signals. If among the three second phase voltage detection signals, a difference between one another exceeds a preset range (for example: the voltages are respectively 10 kV, 10 kV, 0 kV, and differences are 10 kV), it means that there is an abnormality in the second phase voltage detection signals.

If all the second phase voltage detection signals are normal, step S306 is performed. At the same time, the controller 130 will further turn on the power switching elements Er2/Es2/Et2. If there is any one in the second phase voltage detection signals to be abnormal (for example: exceed an expected voltage range), step S309 is performed.

In step S309, if there is any one in the second phase voltage detection signals to be abnormal, the controller 130 will generate an abnormal signal corresponding to the abnormal second detection node (or corresponding to the first circuit element). For example, if the second phase voltage detection signals corresponding to the second detection nodes Nr2/Ns2 are normal but the second phase voltage detection signal corresponding to the second detection node Nt2 is abnormal, it means that the first circuit element adjacent to the second detection node Nt2 (that is, the protection element Et1) is probably abnormal. Therefore, the controller 130 will generate the abnormal signal corresponding to the detection node and/or circuit element.

In step S306, if all the second phase voltage detection signals are normal, the controller 130 will turn on the power switching elements Er2/Es2/Et2 and obtain a plurality of third phase voltage detection signals corresponding to the third detection nodes Nr3/Ns3/Nt3 through the third voltage detector 120C.

In step S307, the controller 130 determines whether all the third phase voltage detection signals are normal or not. If yes, step S308 is performed. At this time, since the voltages of all the detection nodes meet a set threshold value, it means that all the elements of the voltage conversion circuit 110 in the power supply system 100 (the medium voltage system cabinet) operate normally. The detection process can be ended.

If there is any one in the third phase voltage detection signals to be abnormal (for example, exceed an expected voltage range), step S309 is performed. At this time, the controller 130 will generate an abnormal signal corresponding to the abnormal third detection node (or corresponding to the second circuit element). For example, if the third phase voltage detection signals corresponding to the third detection nodes Nr3/Ns3 are normal but the third phase voltage detection signal corresponding to the third detection node Nt3 is abnormal, it means that the second circuit element adjacent to the third detection node Nts3 (that is, the power switching element Et2) is probably abnormal. Therefore, the controller 130 will generate the abnormal signal corresponding to the detection node and/or circuit element.

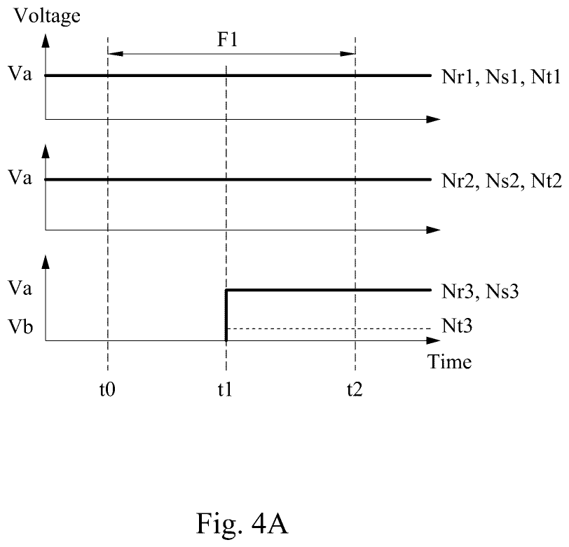

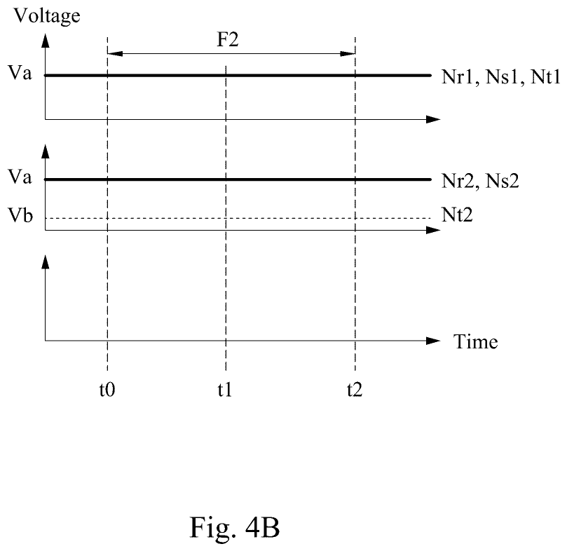

In the above embodiment, although the “obtain the corresponding phase voltage detection signals through the different voltage detectors 120A-120C” is described as different steps, however, in some embodiments the controller 130 can obtain the plurality of phase voltage detection signals through the voltage detectors 120A-120C simultaneously rather than obtain the phase voltage detection signals in sequence. To facilitate understanding, here FIG. 4A and FIG. 4B are taken as an example for illustration.

FIG. 4A depicts phase voltages detected by the power supply system 100 (the medium voltage system cabinet) according to one embodiment. The controller 130 and the voltage detectors 120A-120C receive the electric power provided by the auxiliary power supply during a detection period F1 so as to be driven. In FIG. 4A, the uppermost waveform represents voltages of the three first detection nodes Nr1/Ns1/Nt1 detected by the first voltage detector 120A, the middle waveform represents voltages of the three second detection nodes Nr2/Ns2/Nt2 detected by the second voltage detector 120B, and the lowermost waveform represents voltages of the three third detection nodes Nr3/Ns3/Nt3 detected by the third voltage detector 120C.

As shown in FIG. 4A, during time points t0-t1, the controller 130 obtains the voltage of each of the first detection nodes Nr1/Ns1/Nt1 through the first voltage detector 120A. In the present embodiment, the voltage of each of the first detection nodes Nr1/Ns1/Nt1 is a normal voltage Va.

At the same time, during the time points t0-t1, the controller 130 will further detect the voltage of each of the second detection nodes Nr2/Ns2/Nt2 through the second voltage detector 120B. In the present embodiment, the voltage of each of the second detection nodes Nr2/Ns2/Nt2 is the normal voltage Va, which means that voltages of two terminals of the protection element Er1/Es1/Et1 are all normal, so there is no abnormality in the protection elements Er1/Es1/Et1.

In addition, during the time points t0-t1, since the controller 130 is determining whether there is an abnormality in the protection elements Er1/Es1/Et1 or not, there is no need to make a judgement on the voltages of the third detection nodes NR3/NS3/NT3 during these time points. Hence, during the time points t0-t1, the power switching elements Er2/Es2/Et2 are turned off, and the voltages of the third detection nodes Nr3/Ns3/Nt3 are all zero. In other words, the third voltage detector 120C does not need to detect the voltage of each of the third detection nodes Nr3/Ns3/Nt3. Additionally, it is noted that the controller 130 can obtain and judge the voltage of each of the detection nodes through the voltage detectors 120A-120C simultaneously, and also can obtain and judge the voltage of each of the detection nodes through the voltage detectors 120A-120C in sequence. The present disclosure is not limited in this regard.

After the time point t1, the controller 130 will turn on the power switching elements Er2/Es2/Et2, and detect the voltage of each of the third detection nodes Nr3/Ns3/Nt3 through the third voltage detector 120C. In the present embodiment, the voltages of the third detection node Nr3/Ns3 are normal but the voltage of the third detection node Nt3 is too low, which is abnormal. It means that voltages of two terminals of the power switching element Et2 are abnormal, so the controller 130 can judge/confirm that the power switching element Et2 is abnormal. It is noted that, although in FIG. 4A the normal voltage is marked as Va and the abnormal voltage is marked as Vb, there may be errors in the normal voltages of different detection nodes in other embodiments, but roughly the same. For example, the error between multiple phase voltages detected by the same voltage detector is 10%, and the error between multiple phase voltages on the same conversion subcircuit detected by different voltage detectors is 1%.

FIG. 4B depicts phase voltages detected by the power supply system 100 (the medium voltage system cabinet) according to another embodiment. The controller 130 receives the electric power provided by the auxiliary power supply during a detection period F2 so as to be driven. During the time points t0-t1, the controller 130 detects the voltage of each of the first detection nodes Nr1/Ns1/Nt1 through the first voltage detector 120A. In the present embodiment, the voltage of each of the first detection nodes Nr1/Ns1/Nt1 is the normal voltage Va.

At the same time, during the time points t0-t1, the controller 130 further detects the voltage of each of the second detection nodes Nr2/Ns2/Nt2 through the second voltage detector 120B. In the present embodiment, both the voltages of the second detection nodes Nr2/Ns2 are the normal voltage Va but the voltage of the second detection node Nt2 is the abnormal voltage Vb, which means that voltages of two terminals of the protection element Et1 are abnormal, so the controller 130 will generate an abnormal signal corresponding to the second detection node Nt2 and/or the protection element Et1.

As mentioned above, since the controller 130 has determined that the voltages of the two terminals of the protection element Et1 are abnormal, the voltage of the third detection node Nt3 must be abnormal due to the abnormality of the protection element Et1. In some embodiments, the controller 130 will not need to turn on the power switching elements Er2/Es2/Et2 but will directly generate an abnormal signal to allow operating personnel to perform maintenance and inspection.

Through the above voltage detection method, the controller 130 can detect the voltages of different detection nodes respectively through the voltage detectors 120A-120B. Accordingly, the location where the abnormality probably occurs in the power supply system 100 (the medium voltage system cabinet) can be accurately and efficiently determined for operating personnel to perform immediate repairs.

The previously-mentioned steps S301-S309 are used to detect the phase voltages so as to determine whether the circuit elements in the power supply system 100 (the medium voltage system cabinet) are abnormal or not. In other embodiments, when the controller 130 detects the phase voltages of the different detection nodes, respectively, the controller 130 can also detect the line voltages of the different detection nodes through the voltage detectors 120A-120C. The voltage detectors 120A-120C can generate a plurality of first line voltage detection signals, a plurality of second line voltage detection signals, and a plurality of third line voltage detection signals respectively corresponding to the first detection node Nr1/Ns1/Nt1, the second detection node Nr2/Ns2/Nt2, and the third detection node Nr3/Ns3/Nt3. The controller 130 transits these line voltage detection signals to the power control circuit 111, so that the power control circuit 111 generates a phase-locked control signal based on the line voltage detection signals, or adjusts the power factor based on the line voltage detection signals. The phase-locked control signal is used to generate clock signals applied to the power supply system 100.

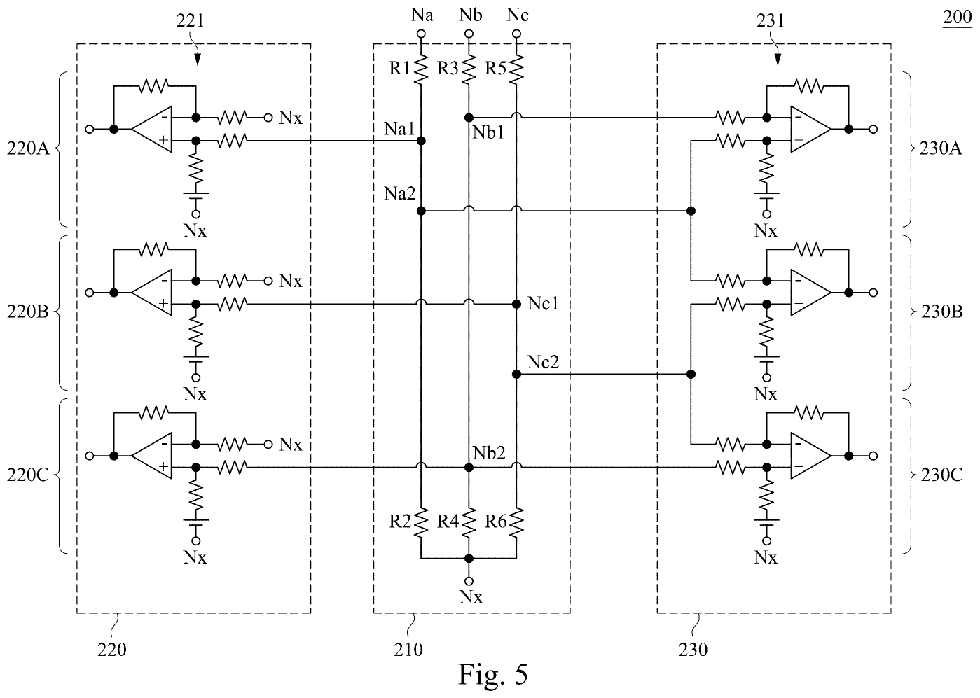

FIG. 5 depicts a schematic diagram of a voltage detector 200 according to some embodiments of the present disclosure. The voltage detector 200 may be applied to each of the voltage detectors 120A-120C in FIG. 1, or applied to the voltage detector 120 shown in FIG. 2. The controller 130 shown in FIG. 1 is coupled to the voltage detectors 120A-120C to receive the phase voltage detection signals or line voltage detection signals transmitted from the voltage detectors 120A-120C.

The voltage detector 200 has a plurality of detection nodes Na/Nb/Nc, and the detection nodes Na/Nb/Nc are configured to be coupled to different detection nodes in the voltage conversion circuit 110. For example, if the voltage detector 200 is configured to be used as the first voltage detector 120A shown in FIG. 1, the detection nodes Na/Nb/Nc are respectively coupled to the first detection nodes Nr1/Ns1/Nt1, and are coupled to the protection elements Er1/Es1/Et1 through the first detection nodes Nr1/Ns1/Nt1 so as to detect the first phase voltage detection signals.

Similarly, if the voltage detector 200 is configured to be used as the second voltage detector 120B shown in FIG. 1, the detection nodes Na/Nb/Nc are respectively coupled to the second detection nodes Nr2/Ns2/Nt2, and are coupled to the protection elements Er1/Es1/Et1 through the second detection nodes Nr2/Ns2/Nt2 so as to detect the second phase voltage detection signals.

Similarly, if the voltage detector 200 is configured to be used as the third voltage detector 120C shown in FIG. 1, the detection nodes Na/Nb/Nc are respectively coupled to the third detection nodes Nr3/Ns3/Nt3, and are coupled to the power switching elements Er2/Es2/Et2 through the third detection nodes Nr3/Ns3/Nt3 so as to detect the third phase voltage detection signals.

A description is provided with reference to FIG. 1 and FIG. 5. The voltage detector 200 includes a voltage dividing circuit 210, a phase voltage detection circuit 220, and a line voltage detection circuit 230. The voltage dividing circuit 210 is coupled to the voltage conversion circuit 110, and includes a plurality of impedance elements R1-R6 and a plurality of voltage dividing nodes Na1/Na2/Nb1/Nb2/Nc1/Nc2. The voltage dividing circuit 210 is configured to divide the AC voltages of the voltage conversion circuit 110 through the impedance elements R1-R6 so as to generate respective divided voltages at the voltage dividing nodes Na1/Na2, Nb1/Nb2, and Nc1/Nc2. For example, the divided voltage of the voltage dividing nodes Na1/Na2 corresponds to the R phase, the divided voltage of the voltage dividing nodes Nb1/Nb2 corresponds to the S phase, and the divided voltage of the voltage dividing nodes Nc1/Nc2 corresponds to the T phase.

In one embodiment, the voltage dividing circuit 210 includes a plurality of voltage dividing subcircuits to respectively receive the AC voltages of different phases and generate the plurality of divided voltages corresponding to the phases. For example, the impedance elements R1/R2 are configured to form a first voltage dividing subcircuit, and are configured to receive the R-phase AC voltage. The impedance elements R3/R4 are configured to form a second voltage dividing subcircuit, and are configured to receive the S-phase AC voltage. The impedance elements R5/R6 are configured to form a third voltage dividing subcircuit, and are configured to receive the T-phase AC voltage.

In one embodiment, one terminals of the plurality of voltage dividing subcircuits are respectively the detection nodes Na/Nb/Nc, and another terminals of the plurality of voltage dividing subcircuits are connected (for example, in a Y connection method) to a same floating node Nx (means the voltage neutral point).

In one embodiment, the voltage dividing circuit 210 is configured to step down the plurality of AC voltages into the divided voltages so as to comply with the operating voltages of the phase voltage detection circuit 220 and the line voltage detection circuit 230.

The phase voltage detection circuit 220 is coupled to the voltage dividing circuit 210 to respectively generate the phase voltage detection signals based on the divided voltage at each of the voltage dividing nodes. In one embodiment, the phase voltage detection circuit 220 includes one or more amplifier circuits 221. The amplifier circuit 221 may include an operational amplifier, an input resistor, and a negative feedback circuit. The amplifier circuits 221 are respectively coupled to the different voltage dividing nodes and correspond to different phases (for example, respectively coupled to the voltage dividing nodes Na1/Nc1/Nb2) to respectively obtain the phase voltage detection signals of different phases. A number of the amplifier circuits 221 may be arbitrarily adjusted depending on detection requirements.

In one embodiment, the phase voltage detection circuit 220 generates a respective phase voltage detection signal corresponding to the phase based on a reference voltage of the floating node Nx and one of the divided voltages. In greater detail, one input terminal (such as the negative terminal) of the amplifier circuit 221 is coupled to the floating node Nx, and another input terminal (such as the positive terminal) of the amplifier circuit 221 is coupled to one of the voltage dividing nodes and/or the floating node Nx. Since those of ordinary skill in the art can understand the operating principle of generating phase voltages by amplifier circuits, a description in this regard is not provided.

The line voltage detection circuit 230 is coupled to the voltage dividing circuit 210, and is coupled to each of the detection nodes through the voltage dividing circuit 210. The line voltage detection circuit 230 is configured to generate the line voltage detection signal based on the divided voltages of a part of the voltage dividing nodes (two nodes corresponding to different phases, such as the voltage dividing nodes Nb1 and Na2). As shown in FIG. 5, the line voltage detection circuit 230 includes one or more amplifier circuits 231. The amplifier circuit 231 may include an operational amplifier, an input resistor, and a negative feedback circuit. Each of the amplifier circuits 231 is coupled to two of the voltage diving subcircuits, so as to obtain the divided voltages corresponding to different phases and generate line voltage detection signal. A number of the amplifier circuits 231 may be arbitrarily adjusted depending on detection requirements.

For example, one input terminal (such as the negative terminal) of the amplifier circuit 231 is coupled to the voltage dividing node Nb1 to obtain the divided voltage corresponding to the S phase. Another input terminal (such as the positive terminal) of the amplifier circuit 231 is coupled to the voltage dividing node Na2 to obtain the divided voltage corresponding to the R phase. The amplifier circuit 231 will generate a line voltage detection signal between the R phase and the S phase based on the divided voltages of the voltage dividing node Nb1 and the voltage dividing node Na2. Similarly, other amplifier circuits 231 can obtain line voltage detection signals between other phases. Since those of ordinary skill in the art can understand the operating principle of generating line voltages by amplifier circuits, a description in this regard is not provided.

The voltage detector 200 according to the present disclosure is applied to a medium voltage system cabinet to convert the AC voltages Vr/Vs/Vt at the kilovolt level into the voltage complying with the operating voltage of the controller (such as 3.3 volts). The voltage dividing circuit 210 usually needs to use resistors with a higher voltage resistance and a large number of resistors. As shown in FIG. 5, in the present embodiment, the voltage detector 200 provides the divided voltages to the phase voltage detection circuit 220 and the line voltage detection circuit 230 through the same voltage dividing circuit. In other words, the voltage detector 200 can use the same resistor board to connect the phase voltage detection circuit 220 and the line voltage detection circuit 230 (that is, the phase voltage detection circuit 220 and the line voltage detection circuit 230 share the same divided voltages), thus forming a simplified voltage detection structure. Accordingly, the circuit elements can be effectively saved and the device cost is improved.

In some embodiments, the voltage detector 200 may further include one or more buffer circuits. The buffer circuit may be a signal follower, and is coupled between voltage dividing circuit 210 and the phase voltage detection circuit 220, and/or coupled between the voltage dividing circuit 210 and the line voltage detection circuit 230.

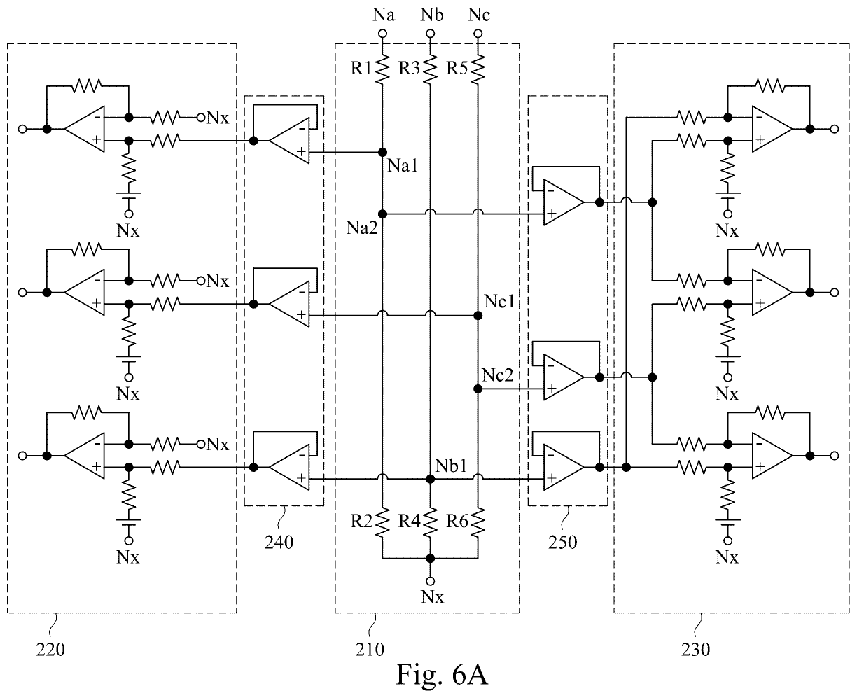

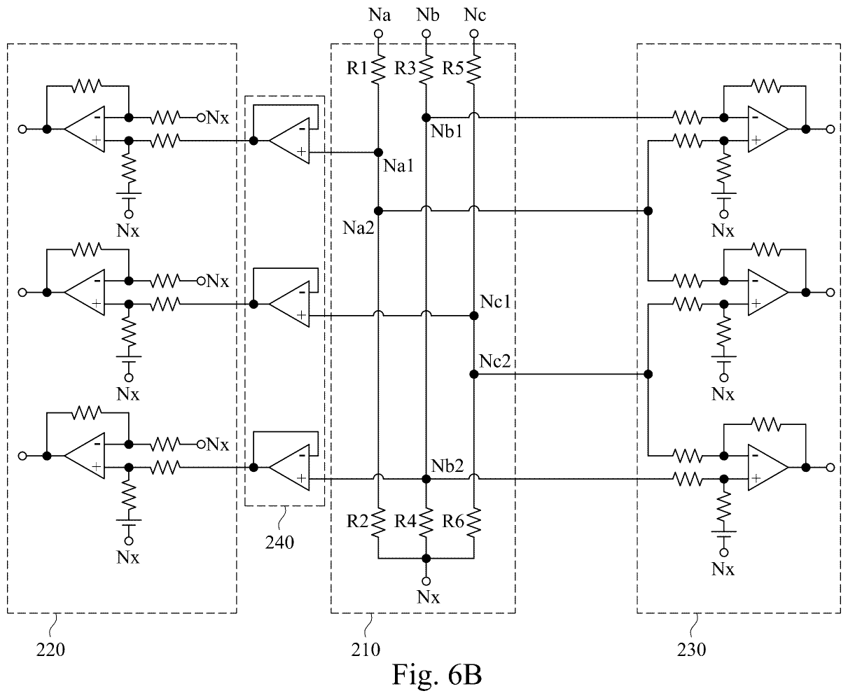

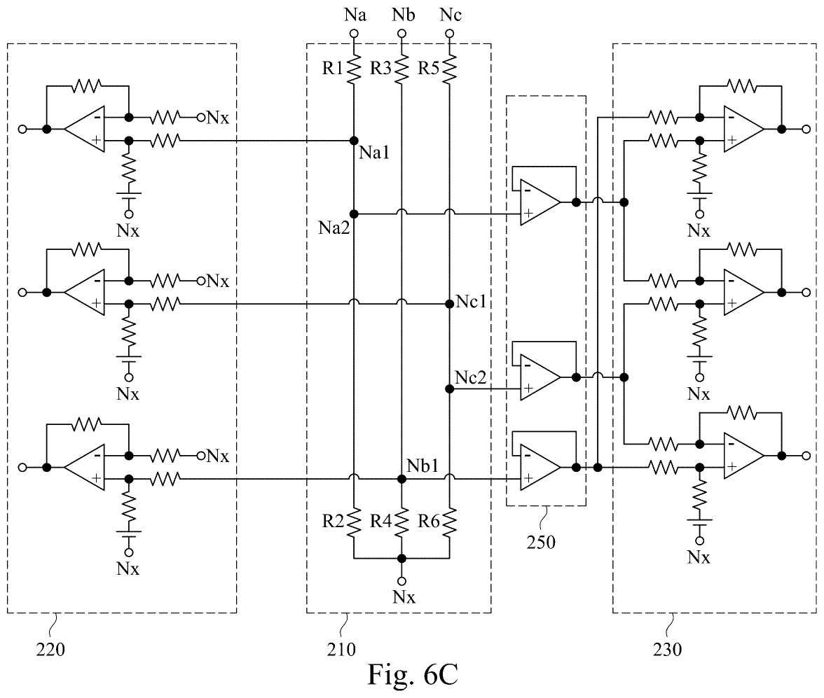

FIG. 6A to FIG. 6C depict schematic diagrams of the voltage detector 200 according to different embodiments of the present disclosure. As shown in FIG. 6A, buffer circuits 240 are coupled between a part of detection nodes of the voltage dividing circuit 210 and the phase voltage detection circuit 220. In greater detail, the buffer circuits 240 are coupled between positive terminals of the amplifier circuits 221 (as shown in FIG. 5) and the voltage dividing subcircuits to prevent the operations of other amplifier circuits 221 from being affected when the part of the amplifier circuits 221 are damaged. Buffer circuits 250 are coupled between a part of the detection nodes of the voltage dividing circuit 210 and the line voltage detection circuit 230. In greater detail, the buffer circuits 250 are coupled between positive terminals of the amplifier circuits 231 (as shown in FIG. 5) and the voltage dividing subcircuits

FIG. 6B depicts a schematic diagram of the voltage detector 200 that only has the buffer circuits 240, and FIG. 6C depicts a schematic diagram of the voltage detector 200 that only has the buffer circuits 250. In other words, disposition positions and quantity of the buffer circuits 250 may be arbitrarily adjusted depending on circuit requirements.

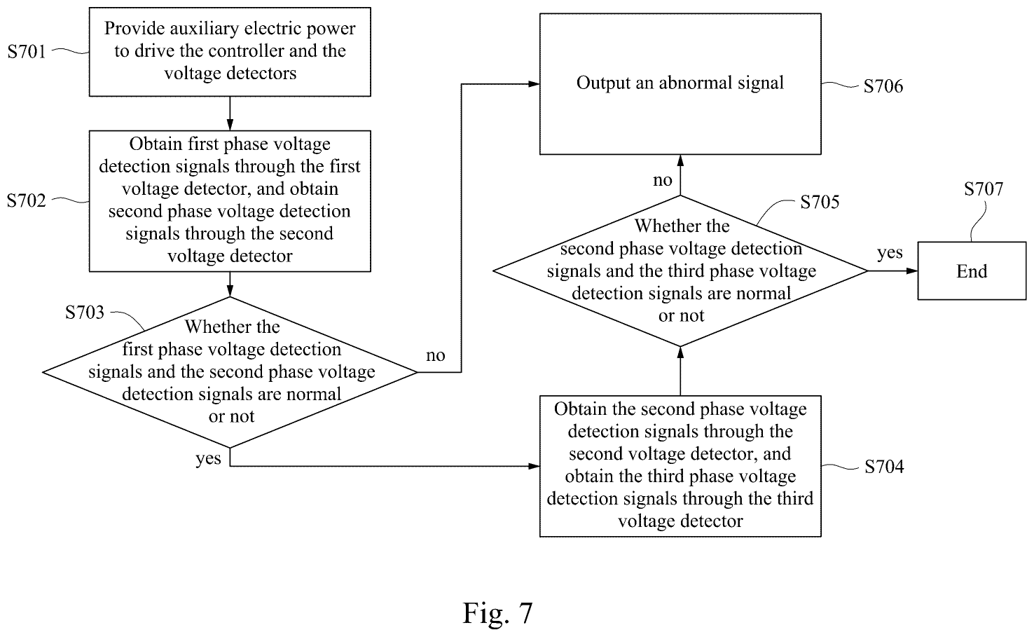

FIG. 7 depicts a flowchart of a voltage detection method according to another embodiment of the present disclosure. In the present embodiment, the power supply system 100 (the medium voltage system cabinet) performs a detection on the voltage conversion circuit 110 through steps S701-S707.

In step S701, the power supply system 100 obtains auxiliary electric power from an auxiliary power supply to drive the controller 130 and the voltage detectors 120A-120C. In step S702, the first voltage detector 120A obtains a plurality of first phase voltage detection signals corresponding to the first detection nodes Nr1/Ns1/Nt1. The second voltage detector 120B obtains a plurality of second phase voltage detection signals corresponding to the second detection nodes Nr2/Ns2/Nt2. The third voltage detector 120C obtains a plurality of third phase voltage detection signals corresponding to the third detection nodes Nr3/Ns3/Nt3. In one embodiment, since at this time the controller 130 will control the power switching elements Er2/Es2/Et2 to be in a turn-off state, the third phase voltage detection signals must be zero.

In step S703, the controller 130 determines whether both the first phase voltage detection signals and the second phase voltage detection signals are normal or not. If both the first phase voltage detection signals and the second phase voltage detection signals are normal, step S704 is performed. If there is any one in the first phase voltage detection signals and the second phase voltage detection signals to be abnormal (for example: exceed an expected voltage range), step S706 is performed to generate an abnormal signal.

For example, if the first phase voltage detection signal corresponding to the first detection nodes Nr is abnormal (for example: exceed the expected voltage range), the controller 130 will generate an abnormal signal corresponding to the first detection node Nr.

If all the first phase voltage detection signals are normal but the second phase voltage detection signal is abnormal, the controller 130 will generate an abnormal signal corresponding to “the abnormal second phase voltage detection signal” or “the abnormal circuit element”. For example, if the first detection node Nr1 is normal but the second phase voltage detection signal of the second detection node Nr2 is abnormal, the controller 130 will generate an abnormal signal corresponding to the second detection node Nr2 (or the protection element Er1).

In step S704, the controller 130 turns on the power switching elements Er2/Es2/Et2. At the same time, the controller 130 obtains the plurality of second phase voltage detection signals corresponding to the second detection nodes Nr2/Ns2/Nt2 through the second voltage detector 120B, and obtains the plurality of third phase voltage detection signals corresponding to the third detection nodes Nr3/Ns3/Nt3 through the third voltage detector 120C. Since, in step S703, it has been confirmed that there is no abnormality in the first detection node Nr1/Ns1/Nt1, there is no need to obtain the plurality of first phase voltage detection signals corresponding to the first detection node Nr1/Ns1/Nt1 at this time. However, in other embodiments, the controller 130 can still continuously obtain the plurality of first phase voltage detection signals corresponding to the first detection nodes Nr1/Ns1/Nt1 through the first voltage detector 120A.

In step S705, the controller 130 determines whether both the second phase voltage detection signals and the third phase voltage detection signals are normal or not. If both the second phase voltage detection signals and the third phase voltage detection signals are normal, step S707 is performed. At this time, since voltages of all the detection nodes meet a set threshold value, it means that all the elements of the voltage conversion circuit 110 in the power supply system 100 (the medium voltage system cabinet) operate normally. As a result, the detection process can be ended.

If there is any one in the second phase voltage detection signals and the third phase voltage detection signals to be abnormal (for example, exceed an expected voltage range), step S706 is performed to generate an abnormal signal. In greater detail, if all the second phase voltage detection signals are normal but the third phase voltage detection signal is abnormal, the controller 130 will generate an abnormal signal corresponding to “the abnormal third phase voltage detection signal” or “the abnormal circuit element”. For example, if the second detection node Nr2 is normal but the third phase voltage detection signal of the third detection node Nr3 is abnormal, the controller 130 will generate an abnormal signal corresponding to the third detection node Nr3 (or the power switching element Er2).

In some embodiments, after confirming that the voltage of each of the detection nodes is normal through the previously-mentioned voltage detection method of FIG. 3 or FIG. 7, the controller 130 can still continuously or regularly receive the first/the second/the third phase voltage detection signals and repeatedly perform the previously-mentioned voltage detection method of FIG. 3 or FIG. 7, so as to monitor the voltage state of the power supply system 100.

The various elements, methods steps, or technical features in the aforementioned embodiments can be combined with each other, and are not limited to the text description order or graphic presentation order of the present disclosure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A power supply system comprising:
a voltage conversion circuit configured to convert an alternating current voltage into a DC voltage; and
at least one voltage detector comprising:
a voltage dividing circuit coupled to the voltage conversion circuit to receive the alternating current voltage, wherein the voltage dividing circuit comprises a plurality of impedance elements and a plurality of voltage dividing nodes to output a plurality of divided voltages;
a phase voltage detection circuit coupled to one of the plurality of voltage dividing nodes of the voltage dividing circuit to generate a phase voltage detection signal based on one of the plurality of divided voltages; and
a line voltage detection circuit coupled to a part of the plurality of voltage dividing nodes of the voltage dividing circuit to generate a line voltage detection signal based on the part of the plurality of divided voltages.

2. The power supply system of claim 1, wherein the voltage conversion circuit comprises a plurality of conversion subcircuits, the plurality of conversion subcircuits is configured to receive a plurality of alternating current voltages of different phases, and the voltage dividing circuit further comprises:
a plurality of voltage dividing subcircuits coupled to the plurality of conversion subcircuits and a floating node to generate the plurality of divided voltages based on the plurality of alternating current voltages, wherein the phase voltage detection circuit generates the phase voltage detection signal based on a reference voltage of the floating node and the one of the plurality of divided voltages.

3. The power supply system of claim 2, wherein the phase voltage detection circuit comprises a plurality of amplifier circuits, one input terminal of each of the plurality of amplifier circuits is coupled to the floating node, another input terminal of each of the plurality of amplifier circuits is coupled to the floating node and one of the plurality of voltage dividing subcircuits.

4. The power supply system of claim 3, wherein the phase voltage detection circuit further comprises:
a plurality of buffer circuits coupled between the plurality of amplifier circuits and the plurality of voltage dividing subcircuits.

5. The power supply system of claim 2, wherein the line voltage detection circuit comprises a plurality of amplifier circuits, each of the plurality of amplifier circuits is coupled two of the plurality of voltage dividing subcircuits so as to generate the line voltage detection signal based on two of the plurality of divided voltages.

6. The power supply system of claim 5, wherein the line voltage detection circuit further comprises
a plurality of buffer circuits coupled between the plurality of amplifier circuits and the plurality of voltage dividing subcircuits.

7. The power supply system of claim 1, wherein the voltage conversion circuit comprises a plurality of protection elements and a plurality of power switching elements, and the at least one voltage detector comprises:
a first voltage detector coupled to the plurality of protection elements and configured to detect a plurality of first phase voltage detection signals; and
a second voltage detector coupled to a plurality of detection nodes between the plurality of protection elements and the plurality of power switching elements, and being configured to detect a plurality of second phase voltage detection signals;
wherein the power supply system further comprises a controller, the controller is coupled to the at least one voltage detector to receive the plurality of first phase voltage detection signals and the plurality of second phase voltage detection signals.

8. The power supply system of claim 7, wherein the controller is configured to compare the plurality of second phase voltage detection signals to determine whether there is an abnormality in the plurality of second phase voltage detection signals or not.

9. The power supply system of claim 8, wherein when the controller determines that there is one of the plurality of second phase voltage detection signals to be abnormal, the controller generates an abnormal signal according to one of the plurality of protection elements corresponding to the one of the plurality of second phase voltage detection signals.

10. The power supply system of claim 7, wherein the voltage conversion circuit further comprises a power control circuit, the power control circuit is coupled to the controller to generate a phase-locked control signal based on the line voltage detection signal.

11. A voltage detection method comprising:
coupling a first voltage detector to a plurality of first detection nodes of a medium voltage system cabinet, and coupling a second voltage detector to a plurality of second detection nodes of the medium voltage system cabinet, wherein the plurality of first detection nodes are coupled between a plurality of phase voltage input nodes and a plurality of first circuit elements, and the plurality of second detection nodes are coupled between the plurality of first circuit elements and a plurality of second circuit elements;
obtaining a plurality of first phase voltage detection signals of the plurality of first detection nodes through the first voltage detector, and obtaining a plurality of second phase voltage detection signals of the plurality of second detection nodes through the second voltage detector;
determining whether the plurality of first phase voltage detection signals and the plurality of second phase voltage detection signals are normal or not through a controller; and
generating an abnormal signal when the plurality of first phase voltage detection signals are normal but one of the plurality of second phase voltage detection signals is abnormal.

12. The voltage detection method of claim 11, further comprising:
turning off the plurality of second circuit elements when determining whether the plurality of first phase voltage detection signals and the plurality of second phase voltage detection signals are normal or not.

13. The voltage detection method of claim 12, wherein the plurality of first circuit elements comprise a plurality of protection elements, one of the plurality of protection elements turns off by itself when a current flowing through the one of the plurality of protection elements exceeds a set threshold value.

14. The voltage detection method of claim 11, further comprising:
generating an abnormal signal corresponding to a corresponding one of the plurality of first circuit elements when the controller determines that the one of the plurality of second phase voltage detection signals is abnormal.

15. The voltage detection method of claim 11, further comprising:
obtaining a plurality of third phase voltage detection signals of a plurality of third detection nodes of the medium voltage system cabinet through a third voltage detector, wherein the third voltage detector is coupled to the plurality of third detection nodes, and the plurality of third detection nodes is coupled between the plurality of second circuit elements and a power control circuit.

16. The voltage detection method of claim 15, further comprising:
generating another abnormal signal corresponding to a corresponding one of the plurality of second circuit elements when the controller determines that one of the plurality of third phase voltage detection signals is abnormal.

17. The voltage detection method of claim 16, wherein the plurality of second circuit elements comprise a plurality of power switching elements.

18. The voltage detection method of claim 11, further comprising:
coupling a plurality of line voltage detection circuits to the plurality of first detection nodes, the second detection nodes, and a plurality of third detection nodes of the medium voltage system cabinet; and
detecting a plurality of first line voltage detection signals, a plurality of second line voltage detection signals, and a plurality of third line voltage detection signals corresponding to the plurality of first detection nodes, the second detection nodes, and the plurality of third detection nodes through the line voltage detection circuits.

19. The voltage detection method of claim 18, further comprising:
generating a phase-locked control signal based on the plurality of first line voltage detection signals, the plurality of second line voltage detection signals, and the plurality of third line voltage detection signals.

20. The voltage detection method of claim 11, wherein the medium voltage system cabinet is configured to receive a plurality of alternating current voltages through the plurality of phase voltage input nodes, and the voltage detection method further comprises:
driving the controller through an auxiliary power supply.
